(19) United States
(12) Patent Application Publication
(10) Pub. No.: US 2013/0147329 A1
(43) Pub. Date: Jun. 13, 2013

(54) CHASSIS OF ELECTRONIC DEVICE WITH HANDLE

(71) Applicant: RONG HU, Shenzhen City (CN)

(72) Inventor: RONG HU, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/330,555

(22) Filed: Dec. 19, 2011

(30) Foreign Application Priority Data
Dec. 12, 2011 (CN) 201110411731.1

(51) Int. Cl. H05K 5/02

(52) U.S. Cl. 312/244

(57) ABSTRACT

A chassis includes a board, a receiving member bounding a receiving space together with the board and having an opening on a side of the receiving space, and a handle. A cutout communicating with the receiving space and the opening is defined in a top of the receiving member. The handle includes an inserting member received in the receiving space through the opening, and an operation member pivotably mounted to the fixing portion. The operation member includes a grip extending out of the receiving space through the cutout.

### BACKGROUND

1. Technical Field

The present disclosure relates to a chassis of an electronic device with a handle.

2.Description of Related Art

Most electronic devices, such as computers, have enclosures to contain electronic elements. Because of the large weight and volume, it is inconvenient to move the enclosures.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an exemplary embodiment of a chassis.

FIG. 2 is an assembled, isometric view of the chassis of FIG. 1.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

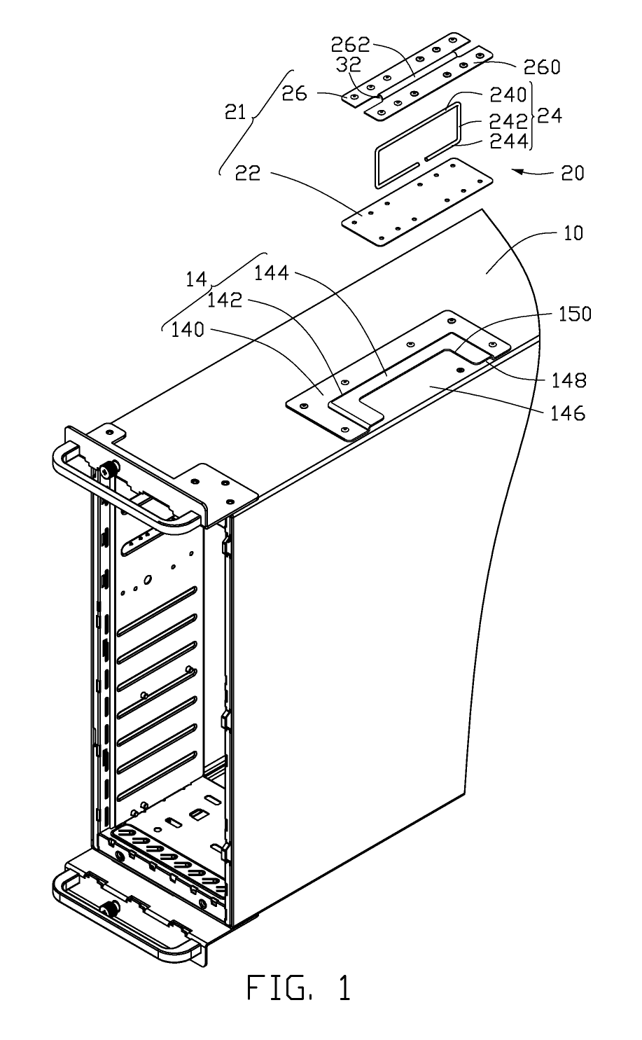

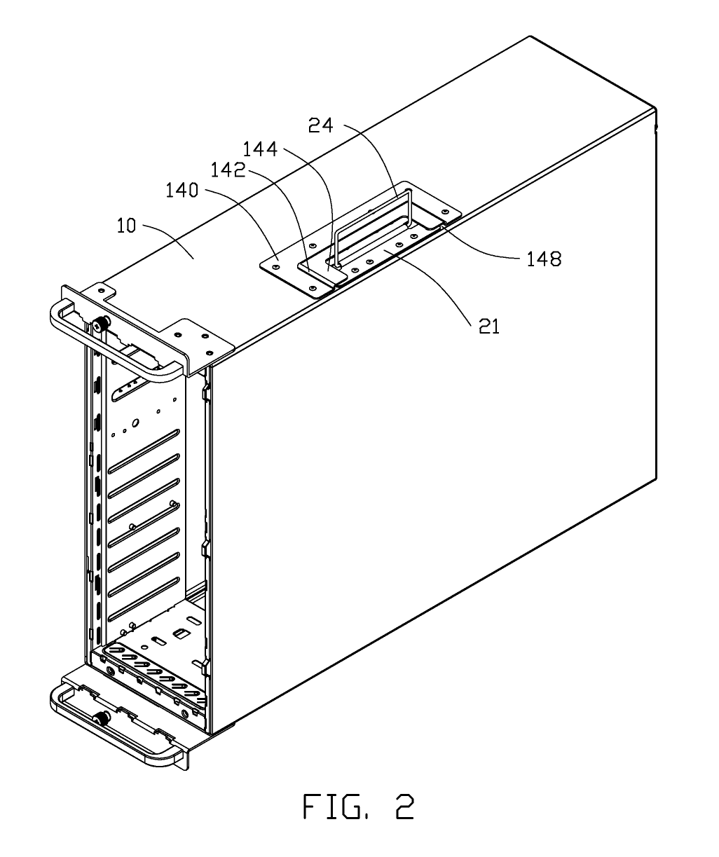

Referring to FIGS. 1 and 2, an exemplary embodiment of a chassis includes a board 10, a receiving member 14 formed on the board 10, and a handle 20.

The receiving member 14 includes a U-shaped fixing piece 140 mounted to the board 20, a U-shaped connection piece 142 extending up from an inner side of the fixing piece 140, and a blocking piece 144 extending from a top of the connection piece 142 away from the fixing piece 140 and substantially parallel to the board 10. A receiving space 146 is bounded by the board 20, the blocking piece 144, and the connection piece 142. The receiving member 14 has an opening 148 on a side of the receiving space 146 opposite to the connection piece 142. A cutout 150 communicates with the receiving space 146 and the opening 148, is defined in the blocking piece 144.

The handle 20 includes an inserting member 21 and an operation member 24. The inserting member 21 includes a plate 22 and a cover 26. The cover 26 includes two coplanar fixing portions 260 mounted on the plate 22 and a connection portion 262 connected between centers of two adjacent sides of the fixing portions 260. The cross-section of the connection portion 262 is substantially C-shaped. A through slot 32 is bounded by the connection portion 262. The operation member 24 is made of a resilient wire, and includes a grip 240, two extension portions 242 perpendicularly extending from opposite ends of the grip 240, and two pins 244 extending toward each other from distal ends of the extension portions 242 opposite to the grip 240. The extension portions 242 are deformed away from each other to insert the pins 244 into opposite ends of the through slot 32, to pivotably mount the operation member 24 to the inserting member 21.

In use, the inserting member 21 is received in the receiving space 146 through the opening 148. The grip 240 is extended out of the cutout 150, ready for be operated to move the chassis.

It is believed that the present embodiments and their advantages will be understood from the foregoing description, and various changes may be made thereto without departing from the spirit and scope of the description or sacrificing all of their material advantages, the examples hereinbefore described merely being exemplary embodiments.

What is claimed is:

1. A chassis, comprising:
a board;
a receiving member mounted on the board, and bounding a receiving space together with the board and having an opening on a side of the receiving space; the receiving member defining a cutout communicating with the receiving space and bounding the opening in a top; and
a handle comprising an inserting member received in the receiving space through the opening, and an operation member pivotably mounted to the inserting member, the operation member comprising a grip extending out of the receiving space through the cutout.

2. The chassis of claim 1, wherein the fixing member defines a through slot in a center, the operation member further comprises two extension portions perpendicularly extending from opposite ends of the grip and two pins extending toward each other from distal ends of the extension portions opposite to the grip to be pivotably engaged in opposite ends of the through slot.

3. The chassis of claim 1, wherein the receiving member comprises a U-shaped fixing piece mounted to the board, a connection piece extending up from an inner side of the fixing piece, and a blocking piece extending from a top of the connection piece and substantially parallel to the board, the cutout is defined in the blocking piece.
